(19) United States
(12) Patent Application Publication
(10) Pub. No.: US 2010/0201671 A1
(43) Pub. Date: Aug. 12, 2010

(54) METHODS AND APPARATUS FOR PRODUCING PRECISION CURRENT OVER A WIDE DYNAMIC RANGE

(75) Inventors: Robert J. Bowman, Fairport, NY (US); Chris J. Nassar, Rochester, NY (US); Carlo Anthony Kosik Williams, Painted Post, NY (US)

Correspondence Address: CORNING INCORPORATED, SP-TI-3-1, CORNING, NY, 14831, US

(73) Assignee: Rochester Institute of Technology

(21) Appl. No.: 12/677,662

(22) PCT Filed: Sep. 9, 2008
(86) PCT No.: PCT/US08/10537

§ 371 Date: Mar. 11, 2010

Related U.S. Application Data
(60) Provisional application No. 60/971,738, filed on Sep. 12, 2007.

(51) Int. Cl. G06F 3/038; H03K 3/00

(52) U.S. Cl. 345/211; 327/108; 345/82

(57) ABSTRACT

Methods and apparatus provide for producing a remote current for driving a load, comprising: producing a local current, Iref; amplifying the local current Iref by a value of K to produce a local current K Iref; mirroring the local current K Iref to another location; producing a remote current K Iref in response to the mirroring of the local current K Iref; and dividing the remote current K Iref by a matched value of K to produce a remote current Iref for driving the load.

### CROSS-REFERENCE TO RELATED APPLICATIONS

This application claims the benefit of priority under 35 U.S.C. §119(e) of U.S. Provisional Application Ser. No. 60/971738 filed on Sep. 12, 2007.

### BACKGROUND

The present invention relates to methods and apparatus for producing a precise and accurate current value at a remote location in response to a programmed current at a local location.

Accurate and precise current values are desirable in a number of applications, including digital-to-analog conversion, image display driving, etc.

For example, in an organic light emitting diode (OLED) display, a plurality of pixels are arranged in rows and columns, where each pixel includes two thin film transistors (TFTs), one an addressing (or switching) transistor and the other a driving (or power) transistor, a storage capacitor, and an OLED device. For activation of a given pixel of the OLED array, a scan line (row line) is selected, and a video signal is loaded on a data line (column line) and input to the driving transistor (via the addressing transistor) to control a current through the OLED device. The video signal is stored on the storage capacitor for the duration of one frame.

An OLED device emits light at intensities proportional to the currents that pass through the device. Therefore, current drive is the preferred OLED driving mode. There are, however, at least two problems that have plagued the OLED display driver industry. The wide dynamic range in OLED pixels requires very small currents at the low end of OLED luminance. The distribution of small, precise currents to remote pixel locations in the OLED array may be corrupted by systemic offset errors and leakage currents leading to non-uniform display luminance. In addition, small currents do not provide adequate drive to quickly settle voltages on column lines with significant distributed capacitance. Thus, the ability to establish the pixel illuminations for the entire array within the time available for a given video frame may be impacted. The above problems are exacerbated as display resolutions increase. Indeed, the available settling times for the array pixels reduce as the resolution increases.

Conventional display driver technology employs thin film transistor circuits to program current or program voltage at the given pixel sites. In current programming, a current is sent to the OLED pixel through a current mirror at the site. In voltage programming, a voltage is converted to a pixel drive current through a pixel drive transistor at the pixel site. These techniques demonstrate reasonable stability but suffer from the aforementioned intensity non-uniformities and slow settling times (particularly at low currents). While voltage programming techniques may tend to settle the pixel site more quickly than current programming, such techniques suffer from systemic transistor mismatches and OLED drive current shifts as the OLED ages.

The problems of illumination non-uniformities and poor settling times have rendered the conventional current techniques for driving OLED arrays unsatisfactory. As a result, the commercial display industry has been slow to adopt OLED technology.

Thus, there is a need in the art for methods and apparatus for providing precise currents to the OLED pixel sites that are accurate over a wide dynamic range, exhibit fast settling times, and maintain accuracy as the OLED devices age.

### SUMMARY

Methods and apparatus according to one or more embodiments of the present invention provide for producing a remote current for driving a load, including: producing a local current, Iref; amplifying the local current Iref by a value of K to produce a local current K·Iref; mirroring the local current K·Iref to another location; producing a remote current K·Iref in response to the mirroring of the local current K·Iref; and dividing the remote current K·Iref by a matched value of K to produce a remote current Iref for driving the load.

In accordance with one or more aspects of the present invention, a current driver circuit includes: a local reference current circuit operable to produce a local current, Iref, and amplify Iref by a value of K to produce a local current K·Iref; a current mirror circuit operable to receive, or source, the local current K·Iref from, or to, the local reference current circuit at a first input and mirror that current at a second input; and a remote current drive circuit operable to produce a remote current K·Iref at the second input of the current mirror circuit in response to the local current K·Iref, and to divide the remote current K·Iref by a matched value of K to produce a remote current Iref for driving a load.

The local reference current circuit may include an up-ratio current generator operable to amplify Iref by K to produce the local current K·Iref. The remote current drive circuit may include a down-ratio current generator operable to divide the remote current K·Iref by the matched value of K to produce the remote current Iref. The up-ratio current generator and the down-ratio current generator may be implemented using ratio-metric design in either monolithic or thin film transistor fabrication technology.

In one or more embodiments, the up-ratio current generator and the down-ratio current generator are operable to vary the value of K as a function of a magnitude of Iref. For example, the up-ratio current generator and the down-ratio current generator may be operable to increase the value of K as the magnitude of Iref reduces and vice versa. The value of K may be between about 100 to about 5000, such as about 1000.

Other aspects, features, and advantages of the present invention will be apparent to one skilled in the art from the description herein taken in conjunction with the accompanying drawings.

### DESCRIPTION OF THE DRAWINGS

For the purposes of illustration, there are forms shown in the drawings that are presently preferred, it being understood, however, that the invention is not limited to the precise arrangements and instrumentalities shown.

FIG. 1 is a schematic diagram of a display array of pixels each having a current driver in accordance with one or more aspects of the present invention;

FIG. 2 is a schematic diagram of an equivalent circuit of a column line of the display array of FIG. 1;

FIG. 3 is a block diagram of a current driver in accordance with one or more aspects of the present invention;

FIG. 4 is a schematic diagram of an exemplary circuit suitable for implementing the current driver of FIG. 3; and

FIG. 5 is a graph illustrating experimental results obtained by measuring the precision of the current driver of the present invention.

### DETAILED DESCRIPTION OF THE PREFERRED EMBODIMENTS

With reference to the drawings, wherein like numerals indicate like elements, there is shown in FIG. 1 a schematic diagram of a display array 100, such as an OLED array, having a plurality of pixels arranged in rows and columns, a local current reference circuit 102, and additional circuitry 106, such as row driver circuits, etc. as would be apparent to one skilled in the art. Each pixel 110 of each column 112, such as pixel (or cell) 110i, includes a number of circuit components for addressing the pixel 110, storing an illumination valued for the pixel, and driving current through an associated OLED device.

For activation of a given pixel 110 of the OLED array 100, a scan (row) line 114, such as line 114i, is selected and an illumination level (derived from the desired frame of video information) is applied on the particular column line, such as column line 112i associated with pixel 110i. The selection of the row line 114i activates the addressing circuitry of the pixel 110i such that the illumination level is stored in the pixel 110i (usually by way of one or more capacitors) and used to set a current level for application to the OLED device. The OLED device of the pixel 110 emits light at intensities proportional to the currents that pass through the device.

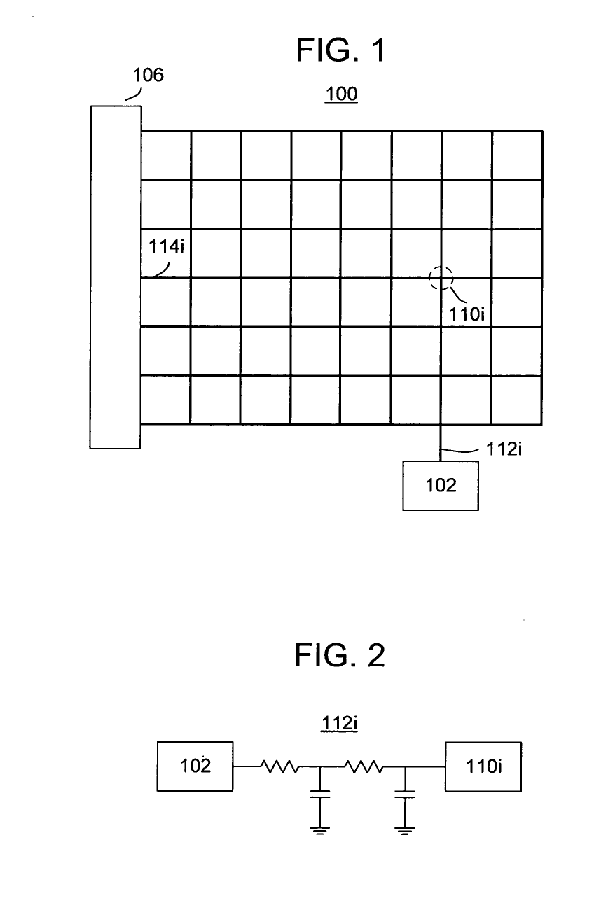

The above process is repeated for each pixel 110 of the array 100 for each frame, at a rate that is typically 30 frames per second (33 ms per frame). Thus, in addition to the desirability of driving a precise current into the OLED device, the rates at which the column lines 112 must ramp from initial values to the final, programmed levels are significant. With reference to FIG. 2, the equivalent circuit for each of the column lines 112 is a distributed R-C circuit. Thus, instantaneous changes in the current through the line 112, and/or changes in the voltage potential on the line 112, are not possible. In accordance with one or more aspects of the present invention, however, the precision of, and rate of change of, the programmed current on the column line 112—and the resultant current available to and/or flowing through the OLED—are addressed in ways not heretofore contemplated in the art.

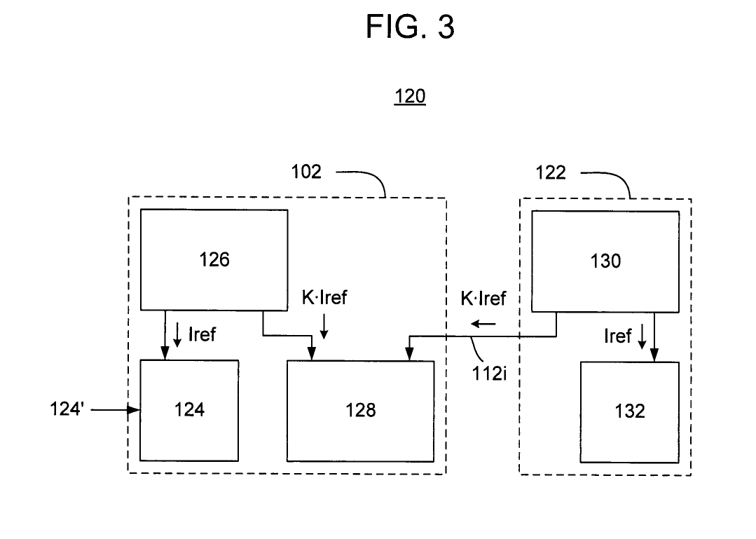

FIG. 3 is a block diagram of a current driver circuit 120 in accordance with one or more aspects of the present invention. The current driver circuit 120 includes the aforementioned local current reference circuit 102 and a remote current driver circuit 122. It is understood that each column line 112 may include a dedicated local current reference circuit 102 or a single local current reference circuit 102 may be shared by more than one column line 112. In the latter case, a multiplexing circuit (not shown) may be employed to couple a given column line 112 to the local current reference circuit 102 for a particular time interval during which the column line 112 is driven to the desired current and voltage levels. Thereafter, the multiplexer couples a next column line 112 to the local current reference circuit 102 for another interval, and so on. It is also understood that each pixel 110 of the array 100 includes a dedicated remote current driver circuit 122.

The local current reference circuit 102 includes a precision current reference 124, an up-ratio current generator circuit 126 and a current mirror circuit 128. The precision current reference 124 either sources or sinks a current, Iref, representing the desired illumination level for a given pixel 110i. The particular level of Iref is computed using graphics processing techniques known in the art and the specific value is controlled via programming line 124′. Assuming that the precision current reference 124 sinks current, the up-ratio current generator circuit 126 sources the current Iref and produces an amplified version of Iref, specifically to produce a local current K·Iref. The up-ratio current generator circuit 126 sources the local current K·Iref into one input of the current mirror circuit 128. Thus, the current mirror circuit 128 will operate to sink an equal current, K·Iref, into its other input, over the column line 112i. In an alterative embodiment, the precision current reference 124 may source current, the up-ratio current generator circuit 126 may sink the currents Iref and K·Iref, and the current mirror circuit 128 may source the currents K·Iref.

The remote current driver circuit 122 includes a down-ratio current generator circuit 130 and a load device 132, such as an OLED device. The down-ratio current generator circuit 130 receives the “remote” current K·Iref over the column line 112i, which is generated by the current mirror circuit 128 (assuming that the current mirror circuit 128 is operating as a current sink). The down-ratio current generator circuit 130 is operable to divide the remote current K·Iref by a matched value of K to produce a remote current Iref for driving the load 132.

The up-ratio current generator circuit 126 is designed to apply a ratio of K/1 to the local current Iref, while the down-ratio current generator circuit 130 is designed to apply a ratio of 1/K to the remote current K·Iref. In order to achieve superior precision in programming the remote current Iref into the load 132, the transistor circuitry of the up-ratio current generator circuit 126 and the down-ratio current generator circuit 130 are implemented using ratio-metric design, which may be implemented using monolithic or thin film transistor fabrication technology on a common semiconductor chip. This may result in a product term K/1.1/K=1.000 (to within 0.1% accuracy). The precision of the product term is enhanced in thin film transistor technologies commonly used in displays because a major source of current mirror error, i.e., substrate leakage currents, do not exist in the isolated mesas of thin film transistor technology. It is this accuracy in product terms that improves the precision of the programmed remote current Iref through the (OLED) load 132 and addresses the significant non-uniform illumination issues experienced in the prior art. In addition, the use of the ratio-metric design of the up-ratio and down-ratio current generator circuits 126, 130 ensures precision over a very wide dynamic range, from about 6 nA to about 6 uA.

Advantageously, the settling time on the column line is significantly faster that in the prior art, particularly at low current programming levels. Indeed, using a value of K between about 100 and 5000, such as 1000 nominal, the magnitude of the current sourcing (or sinking) the remote current K·Iref on the column line 112i is significantly higher (i.e., K times higher) than if the up-ratio current generator circuit 126 were not employed—as is the case in the prior art.

In accordance with one or more embodiments of the present invention, the up-ratio current generator circuit 126 and the down-ratio current generator circuit 130 are operable to vary the value of K as a function of a magnitude of Iref. When the programmed level of the local current Iref is relatively low, such as on the order of 10 nA, it is desirable to have a relatively high level for K. With a high level for K, the effects of leakage currents (and other circuit non-idealities) become less significant when compared to the magnitude of current K·Iref, and the resultant precision of the programmed remote current Iref is thereby achieved. Concurrently, the relatively high level of K insures that the settling time of the column line 112 is reduced, again because of the higher magnitude of K·Iref working against the fixed distributed capacitance of the column line 112.

On the other hand, when the magnitude of the programmed local current Iref is relatively high, such as hundreds of nA, a very high level of K may cause excessive power dissipation and/or the potential for overdriving portions of the circuit. Thus, the up-ratio current generator circuit 126 and the down-ratio current generator circuit 130 are operable to increase the value of K as the magnitude of Iref reduces and decrease the value of K as the magnitude of Iref increases, through control signals on lines 126′ and 130′, respectively. There are no control lines required for the scaling of K as a function of the local current Iref. Indeed, K is an inverse function of the current magnitude due the intrinsic conduction properties of MOSFETs.

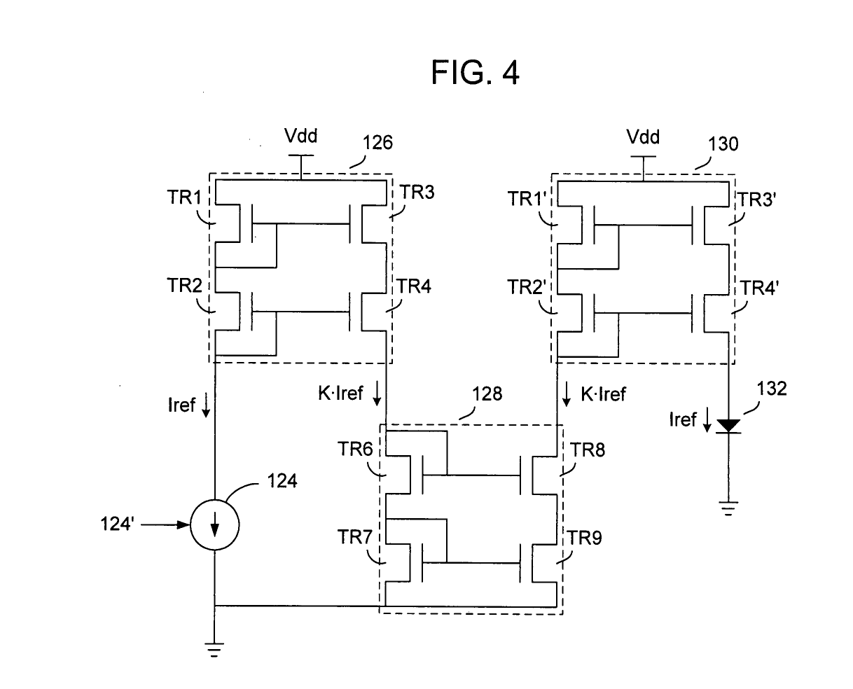

FIG. 4 is a schematic diagram of an exemplary circuit suitable for implementing the current driver circuit 120 of FIG. 3. The precision current reference 124 is implemented using a programmable current source referenced to ground. The up-ratio current generator circuit 126 is implemented using PMOS transistors TR1, TR2, TR3, and TR4, the configuration and gains of which are such that TR3 and TR4 carry K times the current of Iref. The down-ratio current generator circuit 130 is implemented using matched PMOS transistors TR1′, TR2′, TR3′, and TR4′, in a ratiometric design as referenced to TR1, TR2, TR3, and TR4 of the up-ratio current generator circuit 126. Thus the product term K/1·1/K is very close to unity. The current mirror circuit 128 is implemented using NMOS transistors TR6, TR7, TR8, and TR9, the configuration and gains of which are such that the local current K·Iref and the remote current K·Iref flowing over the column line 112i are closely matched.

The parasitic capacitances (gate capacitances) of the transistors TR3′ and TR4′ store a voltage representing the desired remote current Iref for delivery to the load 132. The precision, remote current Iref, therefore, flows into the load device 132, which is shown as an OLED. The lower the stored gate voltages on the PMOS transistors, the higher the current Iref and the greater the light emission from the OLED for the given pixel 110.

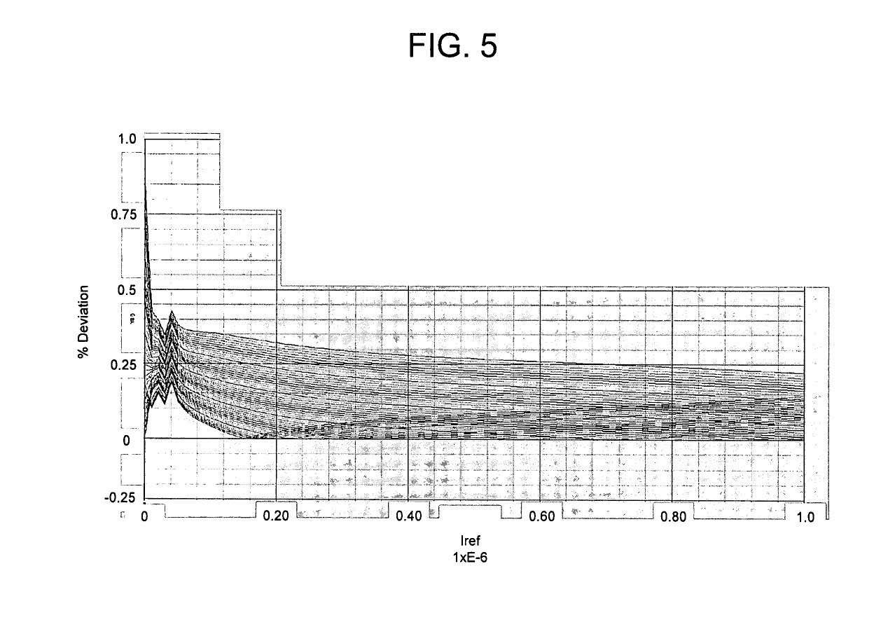

FIG. 5 is a graph illustrating experimental results obtained by measuring the precision of the current driver circuit 120 of the present invention. The Y-axis of the graph is the percentage deviation between the remote current Iref and the local current Iref, while the X-axis is the magnitude of Iref. In mathematical form, the graph illustrates:

|[local Iref−remote Iref]/local Iref|.

Since the percentage deviation is an absolute value, the graph folds over itself. As illustrated, the % error approaches zero at local Iref values between 0 and 160 nA and then begins to increase. The value of the remote current Iref is accurate to within about 1% of the value of the local current Iref over about three orders of magnitude of the current (1 nA to 1 uA).

The foregoing has demonstrated that the various aspects of the present invention have application in OLED arrays; however, one or more aspects of the invention have application in other technical areas, indeed in any application requiring precise currents over a wide dynamic range. For example, applications in which micro-power current levels are used in digital-to-analog converters (DACs). Indeed, employing the current driver of the present invention in a DAC (as would be readily apparent to a skilled artisan from the teaching herein), a 10 bit current DAC would generate current outputs accurate over three orders of magnitude. The aspects of the invention may be used to minimize inaccuracies introduced in the DAC core due to systemic offset and leakage currents. Another application of the invention is in circuits used to mimic the massively parallel connections of the biological nervous system. These circuits are designed to distribute low value, precise currents, over a wide dynamic range. The current driver of the present invention would be readily adaptable by a skilled artisan from the teaching herein to provide the nano-ampere levels of current over these parallel connections with resolutions to one part in a thousand.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A current driver circuit, comprising:
a local reference current circuit operable to produce a local current, Iref, and amplify Iref by a value of K to produce a local current K·Iref;
a current mirror circuit operable to receive, or source, the local current K·Iref from, or to, the local reference current circuit at a first input and mirror that current at a second input; and
a remote current drive circuit operable to produce a remote current K·Iref at the second input of the current mirror circuit in response to the local current K·Iref, and to divide the remote current K·Iref by a matched value of K to produce a remote current Iref for driving a load.

2. The current driver circuit of claim 1, wherein:
the local reference current circuit includes an up-ratio current generator operable to amplify Iref by K to produce the local current K·Iref;
the remote current drive circuit includes a down-ratio current generator operable to divide the remote current K·Iref by the matched value of K to produce the remote current Iref; and
the up-ratio current generator and the down-ratio current generator are implemented using ratio-metric design on a common semiconductor chip.

3. The current driver circuit of claim 2, wherein the up-ratio current generator and the down-ratio current generator are operable to vary the value of K as a function of a magnitude of Iref.

4. The current driver circuit of claim 3, wherein the up-ratio current generator and the down-ratio current generator are operable to increase the value of K as the magnitude of Iref reduces and vice versa.

5. The current driver circuit of claim 1, wherein the value of K is one of: between about 100 to about 5000; and about 1000.

6. The current driver circuit of claim 1, wherein the value of the remote current Iref is accurate to within about 1% of the value of the local current Iref over about three orders of magnitude of the currents Iref.

7. The current driver circuit of claim 6, wherein the value of the remote current Iref is accurate to within about 1% of the value of the local current Iref down to about 6 nA.

8. A current driver circuit for an organic light emitting diode (OLED) array, comprising:
a local reference current circuit operable to produce a local current, Iref, and amplify Iref by a value of K to produce a local current K·Iref;
a current mirror circuit operable to receive, or source, the local current K·Iref from, or to, the local reference current circuit at a first input and mirror that current at a second input; and
a remote current drive circuit operable to produce a remote current K·Iref over a column line of the OLED array for sourcing, or receiving, current to, or from, the second input of the current mirror circuit in response to the local current K·Iref, and to divide the remote current K·Iref by a matched value of K to produce a remote current Iref for driving an OLED at a given pixel of the OLED array.

9. A method of producing a remote current for driving a load, comprising:
producing a local current, Iref;
amplifying the local current Iref by a value of K to produce a local current K·Iref;
mirroring the local current K·Iref to another location;
producing a remote current K·Iref in response to the mirroring of the local current K·Iref; and
dividing the remote current K·Iref by a matched value of K to produce a remote current Iref for driving the load.

10. The method of claim 2, further comprising varying the value of K as a function of a magnitude of Iref.

11. The method of claim 10, further comprising increasing the value of K as the magnitude of Iref reduces and vice versa.
